(19) United States
(12) Patent Application Publication
(10) Pub. No.: US 2014/0332812 A1
(43) Pub. Date: Nov. 13, 2014

(54) WAFER AND SYSTEM AND METHOD FOR TESTING THE WAFER

(71) Applicant: Electronics and Telecommunications Research Institute, Daejeon (KR)

(72) Inventors: Tae Young Kang, Seoul (KR); Byounggun Choi, Daejeon (KR); Kyung Hwan Park, Daejeon (KR)

(73) Assignee: Electronics and Telecommunications Research Institute, Daejeon (KR)

(21) Appl. No.: 14/189,945

(22) Filed: Feb. 25, 2014

(30) Foreign Application Priority Data
May 7, 2013 (KR) 10-2013-0051511

(51) Int. Cl. H01L 21/66

(52) U.S. Cl. CPC H01L 22/34; H01L 22/14
USPC 257/48; 438/18

(57) ABSTRACT

A wafer is provided. The wafer includes at least one field. The field includes at least one chip, and at least one test chip that generates power using a wireless signal, that provides power to the chip, that tests performance of the chip, and that corrects performance of the chip according to a test result.

### CROSS-REFERENCE TO RELATED APPLICATION

This application claims priority to and the benefit of Korean Patent Application No. 10-2013-0051511 filed in the Korean Intellectual Property Office on May 7, 2013, the entire contents of which are incorporated herein by reference.

### BACKGROUND OF THE INVENTION

(a) Field of the Invention

The present invention relates to a system and method for testing a wafer that can test a wafer by wireless.

(b) Description of the Related Art

An existing wafer test system tests a chip by contacting a probe card with a wafer. An existing wafer test system has a merit that it can test various functions of a chip, but there is a drawback that the existing wafer test system should directly contact the entire chip within a wafer and thus requires a long test time. U.S. Pat. No. 8,028,208 determines a state of a chip based on an oscillation frequency of a ring oscillator that is designed at a periphery of a DUT chip by wireless without a probe card.

Because semiconductor production technology is presently growing into a micro-process of several nanometers, a process change rate (process difference) between chips within the same wafer or a process change rate (process difference) between wafers increases. In the future, a process change rate will further increase with development of processes, and when analyzing a chip with only a frequency of a ring oscillator, a probability of misjudgment may increase.

### SUMMARY OF THE INVENTION

The present invention has been made in an effort to provide a system and method for testing a wafer having advantages of being capable of accurately testing by wireless whether a failure of a produced chip exists and information of the chip.

An exemplary embodiment of the present invention provides a wafer. The wafer includes at least one field. The field includes at least one chip, and at least one test chip that generates power using a wireless signal and that provides the power to the chip and that tests performance of the chip and corrects performance of the chip according to a test result.

The test chip may include: an on-chip antenna; a control logic unit that selects at least one of chips within the field according to a command that is received from an external test apparatus through the antenna and that tests performance of the selected chip; and a power generator that generates power using a wireless signal that is received from the external test apparatus through the antenna and that provides the power to the selected chip.

The test chip may further include: an envelope detector that demodulates a command that is received through the antenna and that transfers the demodulated command to the control logic unit; a Tx modulator that modulates a signal corresponding to performance of the tested chip so as to transmit it to the external test apparatus through the antenna; and a clock generator that generates a clock signal for operation of an internal circuit.

The chip may include: a memory; a current source that generates a current using the power; and a voltage generator that generates a reference voltage using the power. A value of a current that is generated by the current source may be adjusted in response to a first control signal of the control logic unit, and a value of a reference voltage that is generated by the voltage generator may be adjusted in response to a second control signal of the control logic unit. The first control signal and the second control signal may be used for adjusting a value of the current and a value of the reference voltage, respectively, so that performance of the chip satisfies an expected value.

The first control signal and the second control signal may each be stored at a memory of the chip, and the first control signal and the second control signal that are stored at the memory may be transferred to the current source and the voltage generator, respectively, when the chip is packaged.

The test chip may further include an analog to digital converter (ADC). A value of a current that is generated in the current source may be tested using the ADC, and a value of a reference voltage that is generated in the voltage generator may be tested using the ADC.

Power that is generated by the power generator may be stored at a capacitor that is disposed at a scribe line, and power that is stored at the capacitor may be provided to the selected chip.

A line that connects the chip and the test chip may be disposed at a scribe line.

The wafer may further include a coil antenna that is disposed at a scribe line of a periphery of the field so as to transmit and receive a signal to and from an external test apparatus.

The test chip may be disposed at a scribe line or may be disposed in an area of a chip that is divided by the scribe line.

The test chip may be removed in a sawing process.

The test chip may be disposed at the inside of the chip.

Another embodiment of the present invention provides a wafer test system. The wafer test system includes: a wafer that includes at least one field; a test terminal that includes a radio frequency identification (RFID) reader function and that tests performance of the wafer by wireless; and an antenna that is connected to the test terminal and is used for wireless communication between the test terminal and the wafer. The field includes: at least one chip; and at least one test chip that generates driving power using a wireless power signal that is received from the test terminal, that selects at least one of chips within the field in response to a first command that is received from the test terminal, that provides the driving power to the selected chip, that tests performance of the selected chip, that transmits a test result to the test terminal, and that corrects performance of the selected chip, when a second command corresponding to the test result is received from the test terminal.

Yet another embodiment of the present invention provides a method of testing a wafer. The method of testing a wafer by wireless includes: receiving, by a test chip within the wafer, a wireless power signal from an external test terminal and generating driving power; selecting, by the test chip, at least one chip of chips within the wafer to correspond to a first command that is received from the external test terminal, providing the driving power to the selected chip, testing performance of the selected chip, and transmitting a test result to the external test terminal; and correcting performance of the selected chip, when the test chip receives a second command corresponding to the test result from the external test terminal.

### BRIEF DESCRIPTION OF THE DRAWINGS

FIGS. 1A and 1B are diagrams illustrating a field including a plurality of product die chips according to an exemplary embodiment of the present invention.

FIGS. 2A and 2B are diagrams illustrating a field including one product die chip according to an exemplary embodiment of the present invention.

FIGS. 3A to 3D are diagrams illustrating a field to which on-chip antennas are connected according to an exemplary embodiment of the present invention.

FIG. 4 is a diagram illustrating a test chip according to an exemplary embodiment of the present invention.

FIG. 5A is a diagram illustrating current sources in which current correction is performed according to an exemplary embodiment of the present invention.

FIG. 5B is a diagram illustrating a current value that is generated in a test current source according to on/off of transistors of FIG. 5A.

FIG. 6 is a diagram illustrating a voltage generator in which voltage correction is performed according to an exemplary embodiment of the present invention.

FIG. 7 is a diagram illustrating a wafer test system according to an exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

According to the present invention, a test chip within a produced wafer generates DC power using a signal that is transmitted from an external test terminal, selects a chip to test, supplies DC power to the selected chip, and transmits good or bad chip determination information and chip correction information to a user (external test terminal). In this case, a communication method that is used between the external test terminal and the wafer may be designed to follow a radio frequency identification (RFID) standard. RFID includes a method of communicating by magnetic coupling in the 13.56 MHz frequency band and a method of communicating using an RF in the 900 MHz or 2.4 GHz band. When a product die chip has a large size, is few in number, and has high current consumption, a wafer test system according to an exemplary embodiment of the present invention may be designed to test a wafer by wireless using an RFID communication system of the 13.56 MHz band. Here, an antenna is produced with a coil in a wafer for magnetic coupling. In contrast, when a product die chip has a small size, is many in number, and has less current consumption like an ultra-high frequency (UHF) RFID tag chip, a wafer test system according to an exemplary embodiment of the present invention may be designed to test a wafer using an RFID communication system of a 900 MHz or 2.4 GHz band. When producing an antenna with an on-chip, the 900 MHz or 2.4 GHz band has a large wavelength. In order to increase efficiency of a wafer test system, when using a millimeter wave or a terahertz wave of 60 GHz as a carrier, an on-chip antenna of a size appropriate to a wafer can be produced.

Hereinafter, a system and method for testing a wireless wafer using a communication system of a frequency band that can produce an on-chip antenna according to an exemplary embodiment of the present invention will be described in detail with reference to the drawings.

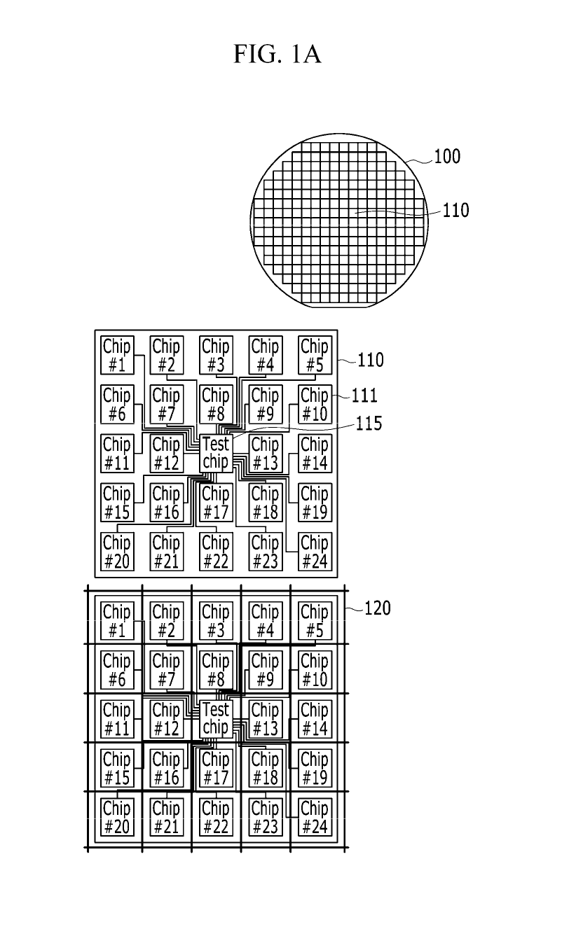

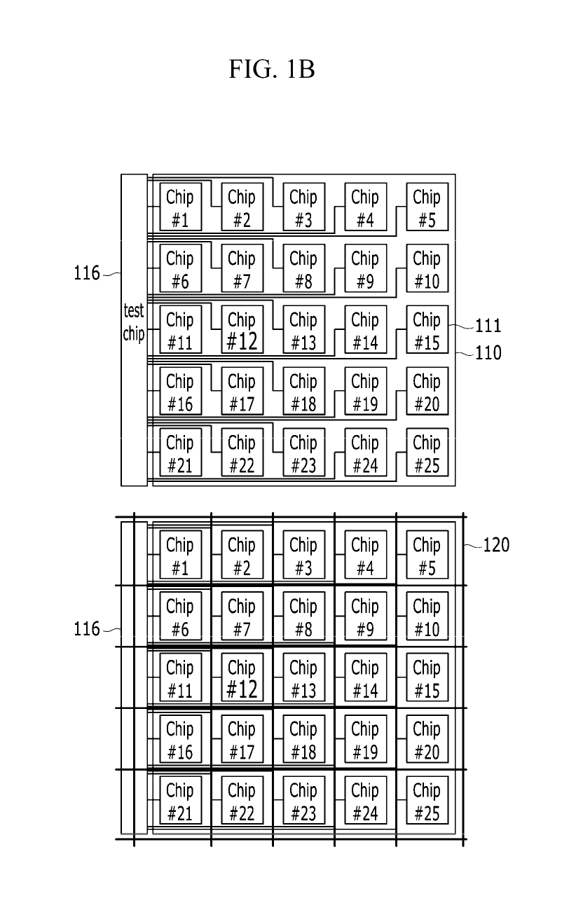

FIGS. 1A and 1B are diagrams illustrating a field 110 including a plurality of product die chips according to an exemplary embodiment of the present invention. Specifically, FIG. 1A is a diagram illustrating a case in which a test chip 115 and a product die chip are formed in an array structure, and FIG. 1B is a diagram illustrating a case in which the test chip 115 is disposed at a scribe line 120.

A wafer 100 includes a plurality of fields 110.

The field 110 includes a plurality of product die chips 111 and at least one test chip 115 and 116. For convenience of description, FIG. 1A illustrates a case in which the field 110 includes 24 product die chips 111 and one the test chip 115, and FIG. 1B illustrates a case in which the field 110 includes 25 product die chips 111 and one test chip 116.

The field 110 may be presently produced in a maximum size of 20 mm×20 mm. As shown in FIG. 1A, because the test chip 115 has a large size, when it is difficult to dispose the test chip 115 at the scribe line 120, the test chip 115 may be formed in an array form in the same size as that of the product die chip 111. That is, the test chip 115 may be disposed at an area of the product die chip 111 (an area in which the product die chip 111 is disposed) that is divided by a scribe line. As shown in FIG. 1B, when the test chip 116 has a small size, the test chip 116 may be disposed at the scribe line 120. As shown in FIGS. 1A and 1B, a connection wire of each of the product die chips 111 and the test chips 115 and 116 is disposed at the scribe line 120 between chips. By using the scribe line 120, which is useless space, a product production cost can be reduced.

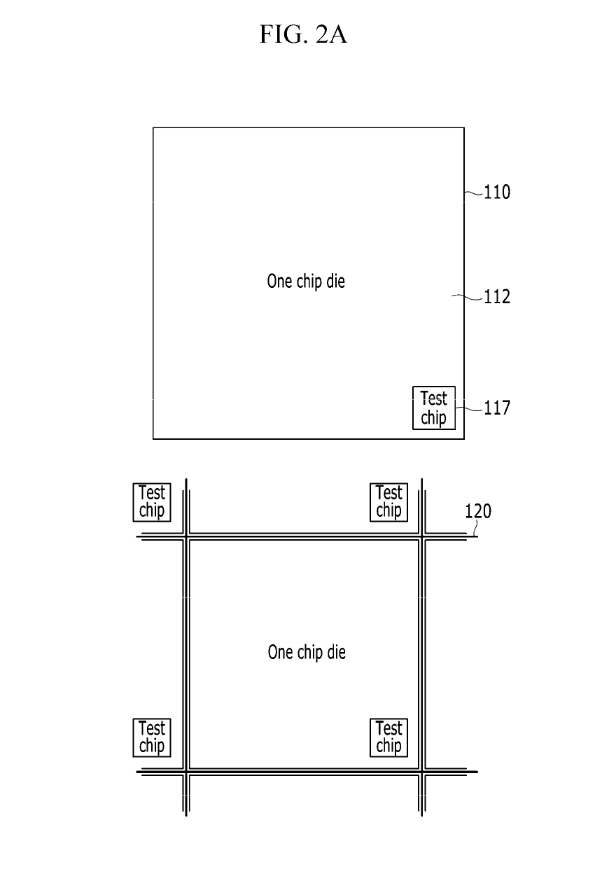

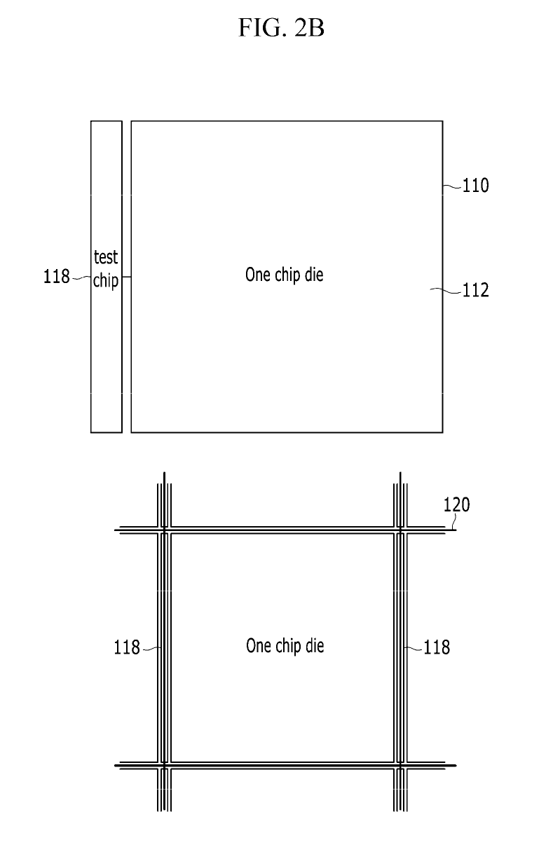

FIGS. 2A and 2B are diagrams illustrating a field 110 including one product die chip 112 according to an exemplary embodiment of the present invention. That is, the field 110 may include one product die chip 112 having a large size. As described above, because the field 110 can be produced at a maximum size of 20 mm×20 mm, the product die chip 112 can be produced with a maximum size of 20 mm×20 mm. Specifically, FIG. 2A illustrates a case in which a test chip 117 is included in the product die chip 112, and FIG. 2B illustrates a case in which a test chip 118 is disposed at the scribe line 120.

Because the product die chip 112 has a large size, when the product die chip 112 cannot be produced in a specific size (e.g., a size of 20 mm×20 mm), the test chip 117 may be included in the product die chip 112, as shown in FIG. 2A. When the test chip 118 may be produced at the scribe line 120, the test chip 118 may be disposed at the scribe line 120 separately from the product die chip 112, as shown in FIG. 2B.

The test chips 116 and 118 that are disposed at the scribe line 120 are removed through sawing work.

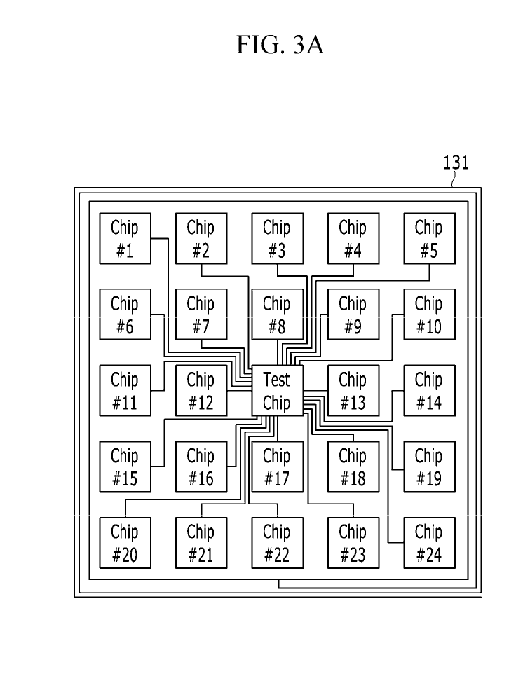

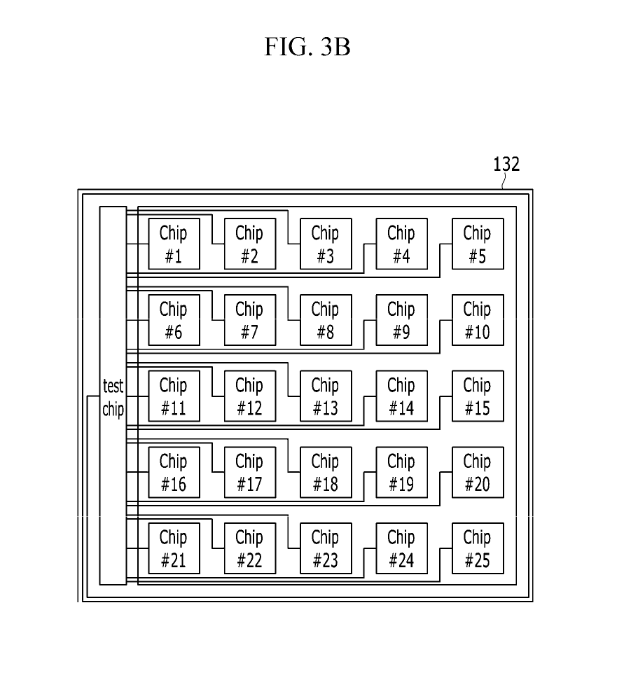

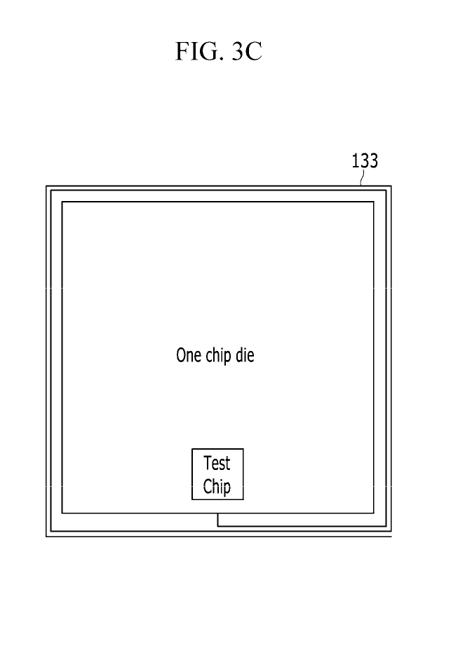

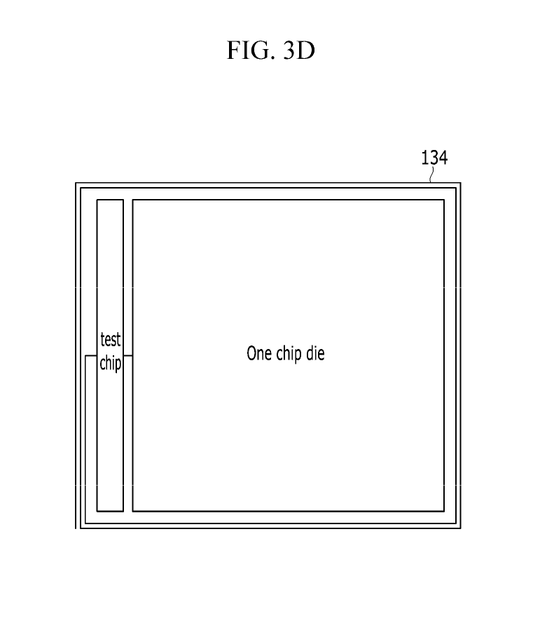

FIGS. 3A to 3D are diagrams illustrating a field 110 to which on-chip antennas 131-134 are connected according to an exemplary embodiment of the present invention.

The on-chip antennas 131-134 may be on-chip coil antennas for magnetic coupling in the 13.56 MHz frequency band. As shown in FIGS. 3A to 3D, the on-chip antennas 131-134 are disposed as metal wires 131-134 at a periphery of the field 110 that is described with reference to FIGS. 1A, 1B, 2A, and 2B. By disposing on-chip coil antennas 131-134 that are produced with metal wires at the scribe line 120 of a periphery of the field 110, production cost can be reduced.

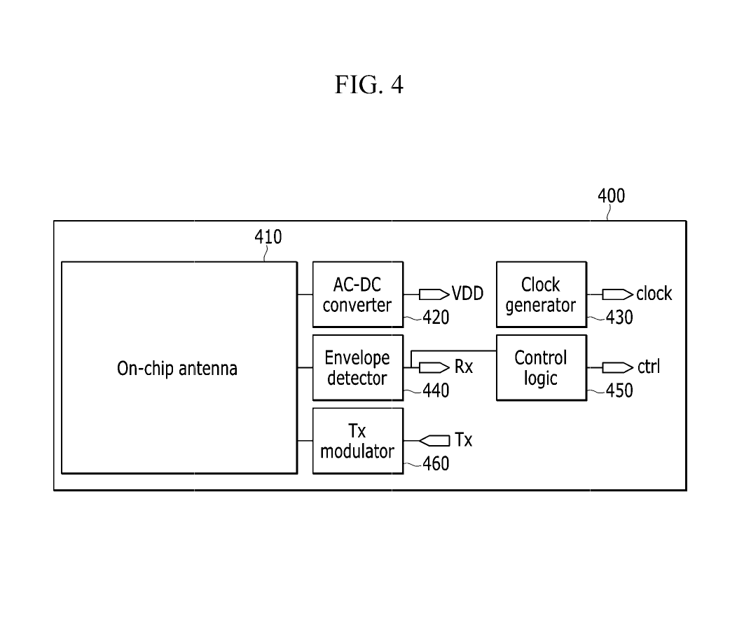

FIG. 4 is a diagram illustrating a test chip 400 according to an exemplary embodiment of the present invention. The test chip 400 of FIG. 4 is the same as the test chips 115-118 that are described with reference to FIGS. 1A, 1B, 2A, and 2B.

The test chip 400 includes an on-chip antenna 410, an AC-DC converter 420, a control logic unit 450, a clock generator 430, an envelope detector 440, and a Tx modulator 460.

The on-chip antenna 410 is required when testing the wafer 100 by wireless with communication using an RF electromagnetic wave. The on-chip antenna 410 is an antenna for an ultrahigh frequency and can be produced in a small size.

The AC-DC converter 420 obtains DC power VDD using a signal that is received from an external test terminal. The AC-DC converter 420 supplies the generated DC power VDD to specific product die chips 111 and 112. That is, the DC power VDD that is generated by the AC-DC converter 420 is used as power of the test chip 400 and the specific product die chips 111 and 112. The DC power VDD that is generated by the AC-DC converter 420 is stored in a capacitor. The capacitor may be disposed at the scribe line 120.

The control logic unit 450 selects the product die chips 111 and 112 to test according to a command that is received from the external test terminal. By connecting DC power VDD that is generated by the AC-DC converter 420 and power of the selected product die chips 111 and 112, the control logic unit 450 controls the DC power VDD to be supplied to the selected product die chips 111 and 112. The control logic unit 450 transmits and receives a command to and from an external test terminal, and tests performance (e.g., electrical characteristics of a chip, operation of a chip) of the selected product die chips 111 and 112. Specifically, a performance of a digital circuit within the selected product die chips 111 and 112 may be tested by receiving acknowledgement (ACK) of a command of the external test terminal. Performance of an analog circuit within the selected product die chips 111 and 112 may be tested through an oscillation frequency that is generated in an oscillator, a reference current, and a reference voltage.

The clock generator 430 generates a clock signal for operation of a digital logic and a memory.

The envelope detector 440 demodulates a command that is transmitted from an external test terminal. A command Rx that is demodulated by the envelope detector 440 is transferred to the control logic unit 450.

The Tx modulator 460 modulates information Tx (e.g., performance information of a tested product die chip) and transmits the modulated information Tx to the external test terminal through the antenna 410.

When the test chip 400 is disposed at the scribe line 120 like the test chips 116 and 118 in FIG. 1B or 2B, constituent elements of the test chip 400 are positioned at the scribe line 120 to be connected to the product die chips 111 and 112 and are removed upon wafer sawing for die separation.

A product die chip having small power consumption and uncomplicated digital logic like an RFID tag chip may perform a full function test of a product using a multiplexer within a product die chip that receives an input of a signal of the test chips 115-118. Good or bad determination of a chip may be ascertained through a full function test of a product, and chip performance correction for a clock signal and a current source is available.

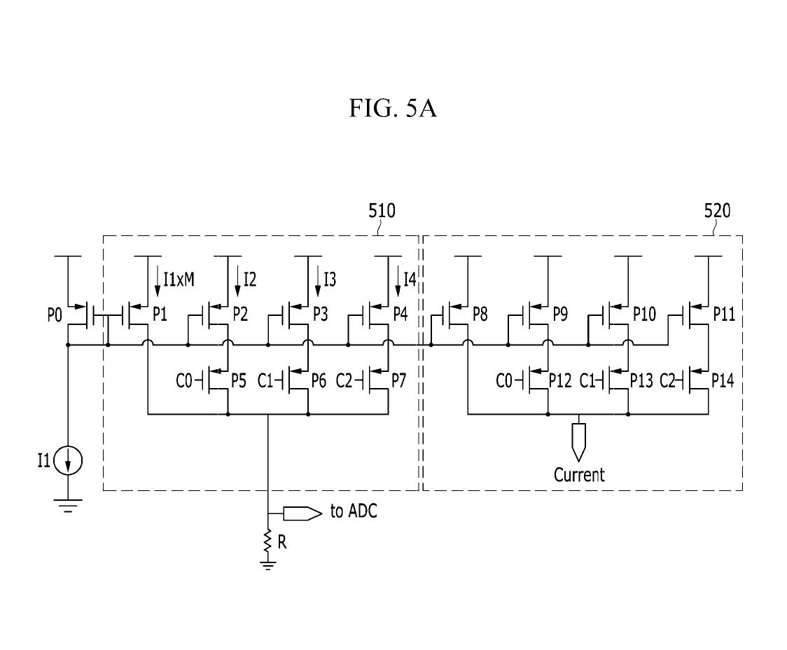

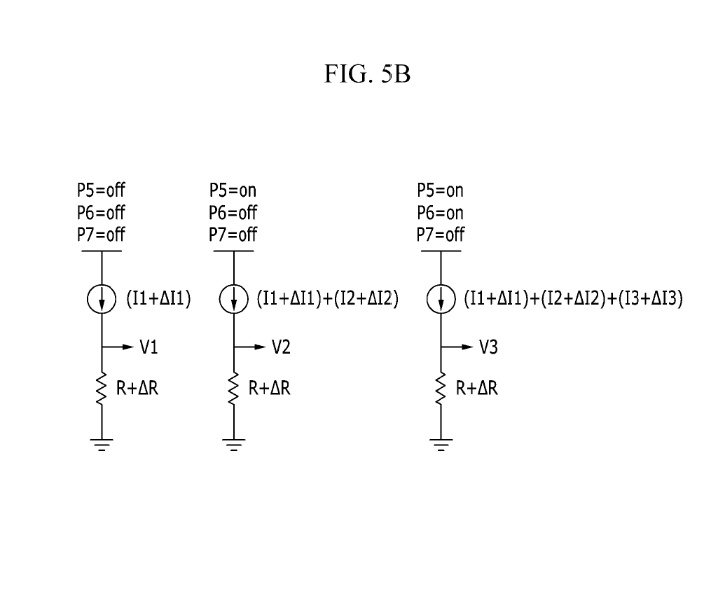

FIG. 5A is a diagram illustrating current sources 510 and 520 in which current correction is performed according to an exemplary embodiment of the present invention. The product die chips 111 and 112 include the current sources 510 and 520. A method of correcting a current according to an exemplary embodiment of the present invention will be described with reference to FIG. 5A.

Because it is difficult to directly test a current value that is generated in the current sources 510 and 520, by testing a voltage according to a resistor R with an analog to digital converter (ADC) using the resistor R or by testing an oscillation frequency occurring when flowing a current to an oscillator, a current value that is generated in the current sources 510 and 520 may be determined. Specifically, the oscillator is included in the product die chips 111 and 112. The ADC may be included in the test chips 115-118 or the product die chips 111 and 112. When the ADC is included in the test chips 115-118, only a signal of a desired product die chip among signals of several product die chips 111 and 112 using a multiplexer may be input to the ADC.

A digital output value or an oscillation frequency of the ADC corresponding to a current value that is generated in the test current source 510 is transmitted to an external test terminal, and the external test terminal adjusts a current value to perform operation in which a product die chip (e.g., 111) wants.

A plurality of current control signals may be transferred to the current sources 510 and 520, and FIG. 5A illustrates a case of using three current control signals C0, C1, and C2 for convenience of description.

A test current may have a value between minimum I1×M and maximum I1×M+I2+I3+I4 through switching of transistors P5, P6, and P7 corresponding to the current control signals C0, C1, and C2. Here, M is a width ratio of P1 and P0, and a width of P1 is M times greater than that of P0. A minimum value and a maximum value of a test current are calculated values in consideration of only widths of transistors P0 and P1 when it is assumed that lengths of the transistors P0 and P1 are the same. Sizes of the transistors P2, P3, and P4 may be the same or different. When values of desired current control signals C0, C1, and C2 are determined, current control signals C0, C1, and C2 to be applied to transistors P12, P13, and P14 of the current source 520 that is used in a system (system including the product die chip (e.g., 111)) are stored at a memory of the product die chip 111. When the product die chip 111 is packaged, the current control signals C0, C1, and C2 that are stored at the memory are transferred to the current source 520. In an analog chip having no memory, chip information and control information (e.g., C0, C1, and C2) may be stored at the external test terminal, transferred to the product die chip upon chip packaging, and used.

FIG. 5A illustrates a case in which the test current source 510 and the current source 520 that is used in a system (system including a product die chip) use the same current control signals C0, C1, and C2, but in some cases, current values of each of the test current source 510 and the current source 520 are separately tested, and each of the test current source 510 and the current source 520 may be controlled using different current control signals. Further, instead of inputting current control signals C0, C1, and C2 to each of the test current source 510 and the current source 520, by adjusting a current I1, two current sources 510 and 520 may be simultaneously controlled. That is, the test chip (e.g., 115), having received a correction command from an external test terminal may adjust the current I1 according to a correction command or may control switching of the transistors P5, P6, and P7 through the current control signals C0-C2.

FIG. 5B is a diagram illustrating a current value that is generated in the test current source 510 according to on/off of the transistors P5-P7 of FIG. 5A. A value in which the designed current sources 510 and 520 are deviated from a designed value and one of the current control signals C0-C2 to be provided to the product die chips 111 and 112 according to the value will be described with reference to FIG. 5B.

Intensity of a test current that is generated in the test current source 510 of FIG. 5A corresponds to intensity of a voltage that is applied to the resistor R within the product die chips 111 and 112. Therefore, by testing intensity of a voltage that is applied to the resistor R through an ADC, intensity of a test current that is generated in the test current source 510 may be known. Hereinafter, for convenience of description, it is assumed that all transistors P0-P4 are designed with the same size, and when all transistors P5-P7 are turned off, a voltage that is applied to the resistor R is V1, when the transistor P5 is turned on when the transistors P6 and P7 are turned off, a voltage that is applied to the resistor R is V2, and when the transistors P5 and P6 are turned on when the transistor P7 is turned off, a voltage that is applied to the resistor R is V3. V1, V2, and V3 may be arranged by Equation 1.

V1=(R+ΔR)×(I1+ΔI1),

V2=(R+ΔR)×((I1+ΔI1)+(I2+ΔI2)),

V3=(R+ΔR)×((I1+ΔI1)+(I2+ΔI2)+(I3+ΔI3)) (Equation 1)

Herein, ΔR is an error in a process change for a resistance design value, and ΔI1, ΔI2, and ΔI3 are errors in a process change for a current design value. Because the transistors P0-P4 are very closely positioned, when a tendency of an error in a process change is the same, Equation 1 may be rearranged as Equation 2.

V1=(R+ΔR)×(I1+ΔI1)=I1R+I1ΔR+ΔI1R+ΔI1ΔR

V2=(R+ΔR)×((2I1+2ΔI1)=2I1R+2I1ΔR+2ΔI1R+2ΔI1ΔR

V3=(R+ΔR)×((3I1+3ΔI1)=3I1R+3I1ΔR+3ΔI1R+3ΔI1ΔR (Equation 2)

Herein, V1, V2, and V3 are each test values of an output of the ADC, and I1R, 2I1R, and 3I1R are design values of V1, V2, and V3, respectively, and thus ΔI1 and ΔR can be obtained from a cubic simultaneous equation of three variables I1ΔR, ΔI1R, and ΔI1ΔR. It is assumed that all sizes of the transistors P1-P4 are the same, but the transistor P1 is actually designed to be larger than the transistors P2-P4. Therefore, when ΔI1 is determined, a current to be further added is determined, and current control signals C0-C2 may be determined. When all transistors P5-P7 are turned off, if intensity of a current flowing by the transistor P1 is larger than a design value, intensity of a current by the transistor P1 may not be reduced and thus a current by the transistor P1 is designed to have a smaller value than a desired value in consideration of a process change.

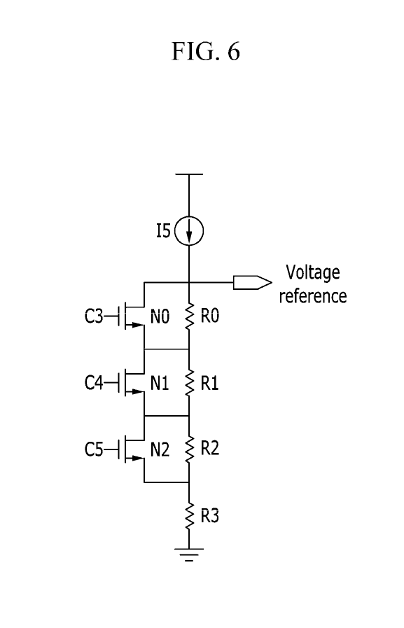

FIG. 6 is a diagram illustrating a voltage generator in which voltage correction is performed according to an exemplary embodiment of the present invention. The product die chips 111 and 112 include a voltage generator of FIG. 6. A method of correcting a voltage according to an exemplary embodiment of the present invention will be described with reference to FIG. 6. As a current I5 flows to resistors R0-R3, a voltage reference is generated, and the current I5 and the resistors R0-R3 may have different values according to a product die chip by a process change. In this case, like a method of correcting a current that is described with reference to FIG. 5A, by adjusting the current I5 or by controlling switching of transistors N0, N1, and N2 according to voltage control signals C3-05, a resistor value may be adjusted. Specifically, when performance of a tested chip does not satisfy an expected value, an external test terminal transmits a correction command that instructs to adjust a reference voltage value to a test chip (e.g., 115). The test chip 115, having received the correction command, adjusts the current I5 according to the correction command or controls switching of the transistors N0, N1, and N2 through the voltage control signals C3-05. Similar to the current control signals C0-C2, when a value of desired voltage control signals C3-05 is determined, the voltage control signals C3-05 are stored at a memory of the product die chips 111 and 112. When the product die chips 111 and 112 are packaged, the voltage control signals C3-05 that are stored at the memory are transferred to the voltage generator.

Because an ADC to convert a reference voltage value to digital does not operate at a high speed, the ADC may be designed with low power. The ADC may be included in the product die chips 111 and 112 or the test chips 115-118.

When performance of the tested chip does not satisfy an expected value by correction such as size adjustment of a passive element (e.g., a resistor or capacitor) and an active element (e.g., a transistor) of the product die chips 111 and 112, the selected product die chip is determined to be faulty. Further, when operation of a digital portion of the product die chips 111 and 112 does not satisfy an expected value by correction, the selected product die chip is determined to be faulty.

When performance of the product die chips 111 and 112 satisfies an expected value through correction, a control signal (e.g., C0-05) for performance correction of an analog portion of the product die chips 111 and 112 and a control signal for performance correction of a digital portion of the product die chips 111 and 112 are stored at a memory of the product die chips 111 and 112. Thereby, the product die chips 111 and 112 may have desired characteristics using a control signal that is stored at the memory without a separate test after wafer sawing and packaging.

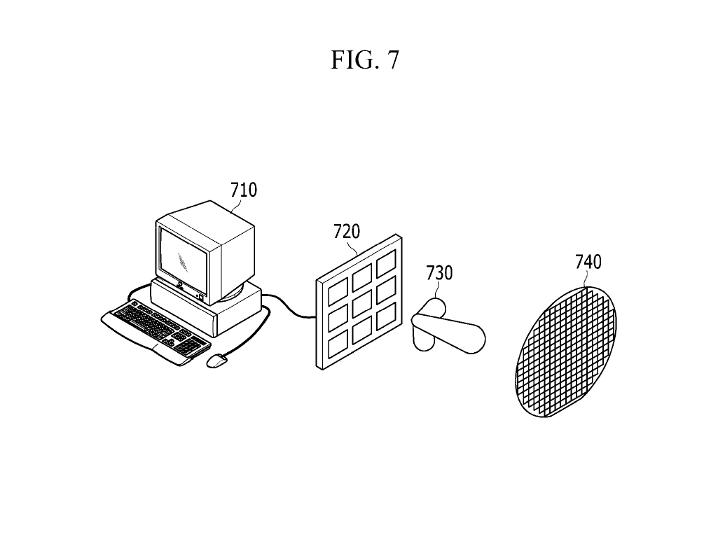

FIG. 7 is a diagram illustrating a wafer test system according to an exemplary embodiment of the present invention.

The wafer test system includes a test terminal 710, an antenna 720, and a wafer 740.

The wafer 740 of FIG. 7 is the same as the above-described wafer 100.

The test terminal 710 includes an RFID reader function. The test terminal 710 transmits a wireless power signal and a command for wafer test to the wafer 740, and receives performance information of the tested chip from the wafer 740.

The antenna 720 is connected to the test terminal 710. The test terminal 710 and the wafer 740, which is a test target, perform wireless communication through the antenna 720. When using a frequency of the 13.56 MHz band, the antenna 720 may be designed as a coil antenna. When using a millimeter wave or a terahertz wave as a carrier, the antenna 720 may be designed as an antenna of an array structure for beamforming 730.

Operation of the wafer test system of FIG. 7 is as follows. The test chips 115-118 within the wafer 740 transmit test information of the product die chips 111 and 112 within the wafer 740 to the test terminal 710, and the test terminal 710 analyzes the received test information and transmits correction information (e.g., current control signals C0-C2, voltage control signals C3-05) to the test chips 115-118. The test chips 115-118 enable the received correction information to be stored at a memory within the product die chips 111 and 112.

According to an exemplary embodiment of the present invention, bad or good of the product die chips 111 and 112 may be determined in a wafer 100 state using a frequency band that can manufacture an antenna with an on-chip.

One field 110 includes at least one of test chips 115-118. The test chips 115-118 generate and operate power using a high frequency signal that is applied from the test terminal 710 through the external antenna 720. By testing performance within the product die chips 111 and 112 through wireless communication with the test chips 115-118, bad or good of the product die chips 111 and 112 may be determined or performance correction may be performed.

A conventional method of testing a wireless wafer may have been known only a wafer state of a position of a product die chip, but according to an exemplary embodiment of the present invention, whether a chip is normally operated and correction information for a desired operation can be obtained. Thereby, whether a failure of a product die chip and information of the chip can be accurately grasped before wafer sawing without contact of a probe card. A chip in which correction is impossible based on the grasped information is not produced in a package, and a chip in which correction is possible is corrected before being produced in a package through a digital correction circuit within the chip. That is, according to an exemplary embodiment of the present invention, good or bad determination and performance correction functions of a product die chip are performed through a no-power wireless communication test chip including a coil or an antenna. Thereby, a test cost can be reduced and unnecessary packaging can be previously prevented, and thus product competitive power can be enhanced.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A wafer comprising at least one field,
wherein the field comprises:
at least one chip; and
at least one test chip that generates power using a wireless signal and that provides the power to the chip and that tests performance of the chip and corrects performance of the chip according to a test result.

2. The wafer of claim 1, wherein the test chip comprises:
an on-chip antenna;
a control logic unit that selects at least one of chips within the field according to a command that is received from an external test apparatus through the antenna and that tests performance of the selected chip; and
a power generator that generates power using a wireless signal that is received from the external test apparatus through the antenna and that provides the power to the selected chip.

3. The wafer of claim 2, wherein the test chip further comprises:
an envelope detector that demodulates a command that is received through the antenna and that transfers the demodulated command to the control logic unit;
a Tx modulator that modulates a signal corresponding to performance of the tested chip so as to transmit it to the external test apparatus through the antenna; and
a clock generator that generates a clock signal for operation of an internal circuit.

4. The wafer of claim 3, wherein the chip comprises:
a memory;
a current source that generates a current using the power; and
a voltage generator that generates a reference voltage using the power,
wherein a value of a current that is generated by the current source is adjusted in response to a first control signal of the control logic unit,
a value of a reference voltage that is generated by the voltage generator is adjusted in response to a second control signal of the control logic unit, and
the first control signal and the second control signal are used for adjusting a value of the current and a value of the reference voltage, respectively, so that performance of the chip satisfies an expected value.

5. The wafer of claim 4, wherein the first control signal and the second control signal each are stored at a memory of the chip, and the first control signal and the second control signal that are stored at the memory are transferred to the current source and the voltage generator, respectively, when the chip is packaged.

6. The wafer of claim 4, wherein the test chip further comprises an analog to digital converter (ADC),
a value of a current that is generated in the current source is tested using the ADC, and
a value of a reference voltage that is generated in the voltage generator is tested using the ADC.

7. The wafer of claim 2, wherein power that is generated by the power generator is stored at a capacitor that is disposed at a scribe line, and
power that is stored at the capacitor is provided to the selected chip.

8. The wafer of claim 1, wherein a line that connects the chip and the test chip is disposed at a scribe line.

9. The wafer of claim 1, further comprising a coil antenna that is disposed at a scribe line of a periphery of the field so as to transmit and receive a signal to and from an external test apparatus.

10. The wafer of claim 1, wherein the test chip is disposed at a scribe line.

11. The wafer of claim 10, wherein the test chip is removed in a sawing process.

12. The wafer of claim 1, wherein the test chip is disposed in an area of a chip that is divided by a scribe line.

13. The wafer of claim 1, wherein the test chip is disposed at the inside of the chip.

14. A wafer test system, comprising:
a wafer that comprises at least one field;
a test terminal that comprises a radio frequency identification (RFID) reader function and that tests performance of the wafer by wireless; and
an antenna that is connected to the test terminal and is used for wireless communication between the test terminal and the wafer,
wherein the field comprises:
at least one chip; and
at least one test chip that generates driving power using a wireless power signal that is received from the test terminal, that selects at least one of chips within the field in response to a first command that is received from the test terminal, that provides the driving power to the selected chip, that tests performance of the selected chip, that transmits a test result to the test terminal, and that corrects performance of the selected chip, when a second command corresponding to the test result is received from the test terminal.

15. The wafer test system of claim 14, wherein the antenna is one of a single coil antenna and an array antenna.

16. A method of testing a wafer by wireless, the method comprising:
receiving, by a test chip within the wafer, a wireless power signal from an external test terminal and generating driving power;
selecting, by the test chip, at least one chip of chips within the wafer to correspond to a first command that is received from the external test terminal, providing the driving power to the selected chip, testing performance of the selected chip, and transmitting a test result to the external test terminal; and
correcting performance of the selected chip, when the test chip receives a second command corresponding to the test result from the external test terminal.

17. The method of claim 16, wherein the second command is a command that instructs to correct the selected chip, when the test result is less than an expected value.

18. The method of claim 17, wherein the correcting of performance comprises:
transmitting, by the test chip, a first control signal for adjusting a value of a current in response to the second command to the selected chip; and
transmitting, by the test chip, a second control signal for adjusting a value of a reference voltage in response to the second command to the selected chip.

19. The method of claim 18, wherein the selected chip comprises:
a memory;
a current source that generates the current using the driving power; and
a voltage generator that generates the reference voltage using the driving power,
wherein a value of a current that is generated by the current source is adjusted in response to the first control signal, and
a value of a reference voltage that is generated by the voltage generator is adjusted in response to the second control signal.

20. The method of claim 19, further comprising storing the first control signal and the second control signal at the memory of the selected chip.
